(19) United States
(12) Patent Application Publication
(10) Pub. No.: US 2018/0151638 A1
(43) Pub. Date: May 31, 2018

(54) ORGANIC LIGHT-ENITTING DIODE DISPLAY PANEL FOR FINGERPRINT RECOGNITION AND ELECTRONIC DEVICE

(71) Applicant: NANCHANG O-FILM BIO-IDENTIFICATION TECHNOLOGY CO., LTD., Nanchang (CN)

(72) Inventors: Jianfeng LUO, Nanchang (CN); Saixin GUAN, Nanchang (CN)

(73) Assignee: NANCHANG O-FILM BIO-IDENTIFICATION TECHNOLOGY CO., LTD., Nanchang (CN)

(21) Appl. No.: 15/585,014

(22) Filed: May 2, 2017

(30) Foreign Application Priority Data
Nov. 28, 2016 (CN) 201611063657.8

(51) Int. Cl. H01L 27/32; G06K 9/00

(52) U.S. Cl. CPC H01L 27/3227; H01L 27/3218; G06K 9/0004

(57) ABSTRACT

An OLED display panel for fingerprint recognition includes a plurality of pixel areas arranged in arrays, the pixel area includes a pixel unit and a fingerprint recognition unit, which are adjacent to each other, the pixel unit is configured to emit light of different colors, the fingerprint recognition unit comprises a sensing light emitting module and a sensing light receiving module, the sensing light emitting module is configured to emit sensing light to a finger, and the sensing light receiving module is configured to receive the sensing light reflected by the finger and convert a light signal of the sensing light into an electric signal. An electronic device having the OLED display panel is also provided.

### CROSS REFERENCE TO RELATED APPLICATION

This application claims priority to Chinese Patent Application No. 2016110636578, entitled “ORGANIC LIGHT-EMITTING DIODE DISPLAY SCREEN FINGERPRINT RECOGNITION EQUIPMENT AND ELECTRONIC DEVICE” filed on Nov. 28, 2016, the contents of which are expressly incorporated by reference herein in its entirety.

### FIELD OF THE INVENTION

The present disclosure relates to the field of display technology, and more particularly relates to an organic light-emitting diode (OLED) display panel for fingerprint recognition and an electronic device having the same.

### BACKGROUND OF THE INVENTION

The OLED display device has advantages of high luminous efficiency, fast response time, being more flexible, emitting light without backlight, thus being applied widely. At the same time, with the rise of the fingerprint recognition technology, the developers begin to research how to apply the fingerprint recognition technology to the OLED display device, so as to enhance safety and operability thereof.

A conventional capacitance fingerprint sensing device is separately arranged for fingerprint recognition in non-display area of the OLED display device. The capacitance fingerprint sensing device has a complicated structure needed to be disposed in non-display area of the display device, which enlarges the non-display area and has an influence on the overall structure of the display device, and OLED display technology cannot integrate with the fingerprint recognition technology to achieve the full-screen fingerprint recognition.

### SUMMARY

The present disclosure is directed to an OLED display panel for fingerprint recognition and an electronic device having the same.

The OLED display panel for fingerprint recognition includes a plurality of pixel areas arranged in arrays, each pixel area includes a pixel unit and a fingerprint recognition unit, which are adjacent to each other, the pixel unit is configured to emit colorful image light, the fingerprint recognition unit includes a sensing light emitting module and a sensing light receiving module, the sensing light emitting module is configured to emit sensing light to a finger, and the sensing light receiving module is configured to receive the sensing light reflected by the finger and convert a light signal of the sensing light into an electric signal.

The electronic device includes the OLED display panel for fingerprint recognition and a motherboard electrically coupled to the OLED display panel, and the motherboard is configured to control the pixel unit to display image and process the electric signal.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

To illustrate the technical solutions according to the embodiments of the present disclosure or in the prior art more clearly, the accompanying drawings for describing the embodiments or the prior art are introduced briefly in the following. The accompanying drawings in the following description are only some embodiments of the present invention, and persons of ordinary skill in the art can derive other obvious variations from the accompanying drawings without creative efforts.

FIG. 1 is a top view of an OLED display panel for fingerprint recognition according to an embodiment;

FIG. 2 is an enlarged, top view of a pixel area according to a first embodiment;

FIG. 3 is a perspective view of the pixel area of FIG. 2;

FIG. 4 is a working principle diagram of a fingerprint unit of the OLED display panel of FIG. 1;

FIG. 5 is a top view of the pixel area of the OLED display panel for fingerprint recognition according to the second embodiment; and

FIG. 6 is a cross-section view of an electronic device of an embodiment.

### DETAILED DESCRIPTION OF THE EMBODIMENTS

The accompanying drawings according to the embodiments of the present disclosure will be described in the following to illustrate the technical solutions according to the embodiments of the present disclosure more clearly and completely. The described implementations are merely specific embodiments of the present disclosure, and any implementations derived from the foregoing implementations without creative efforts by persons skilled in the art shall all fall within the protection scope of the present disclosure.

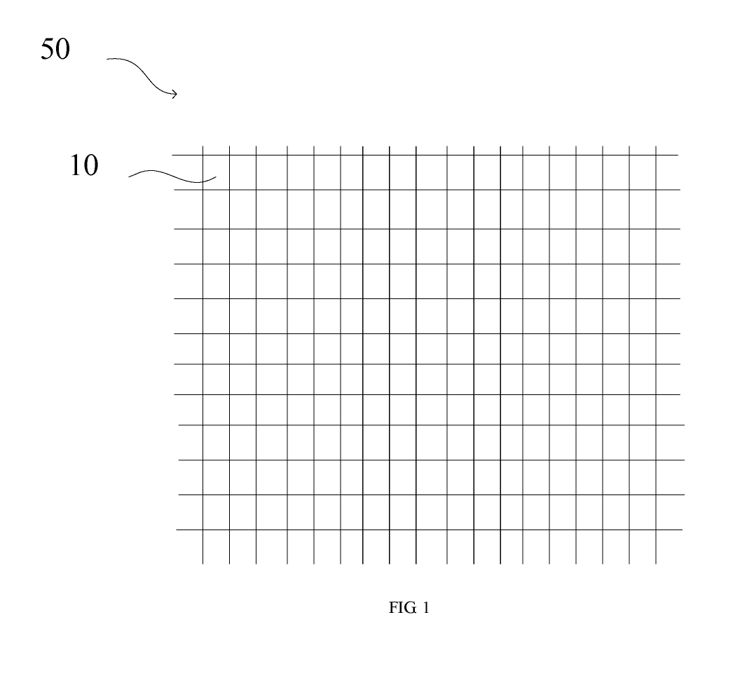

Referring to FIG. 1, an OLED display panel 50 according to an embodiment includes a plurality of pixel areas 10 arranged in arrays.

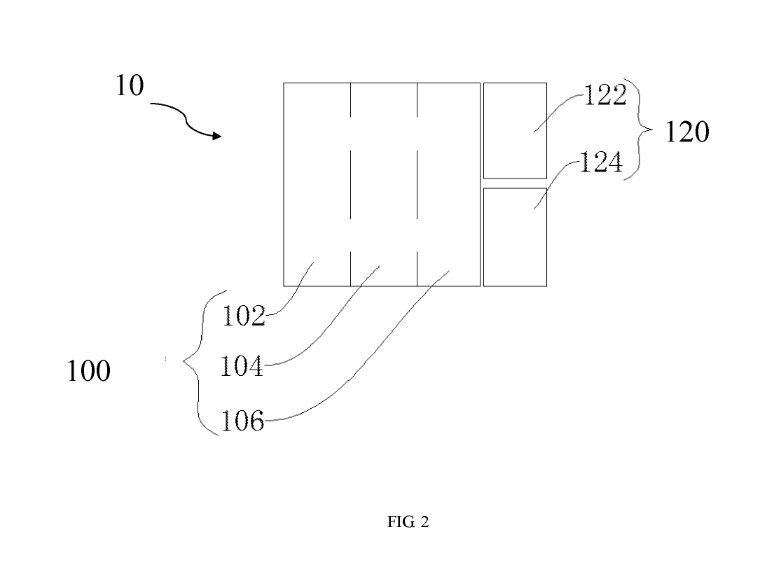

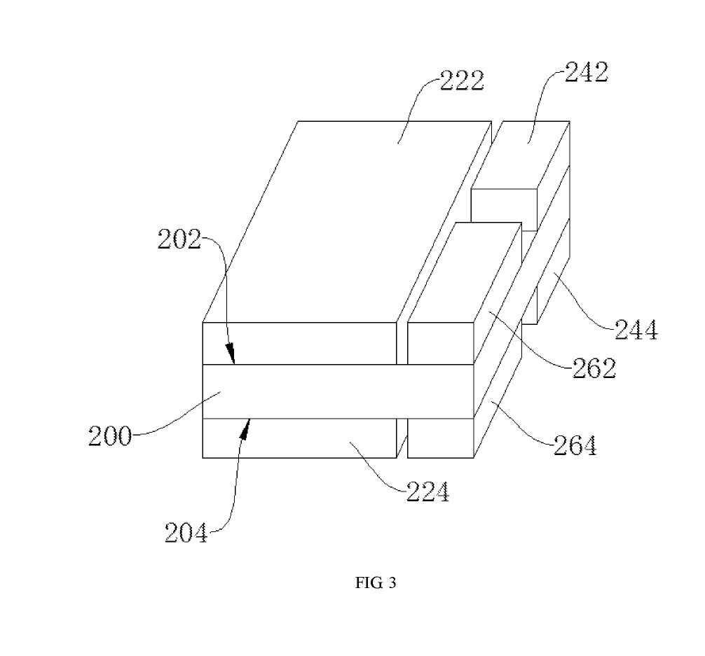

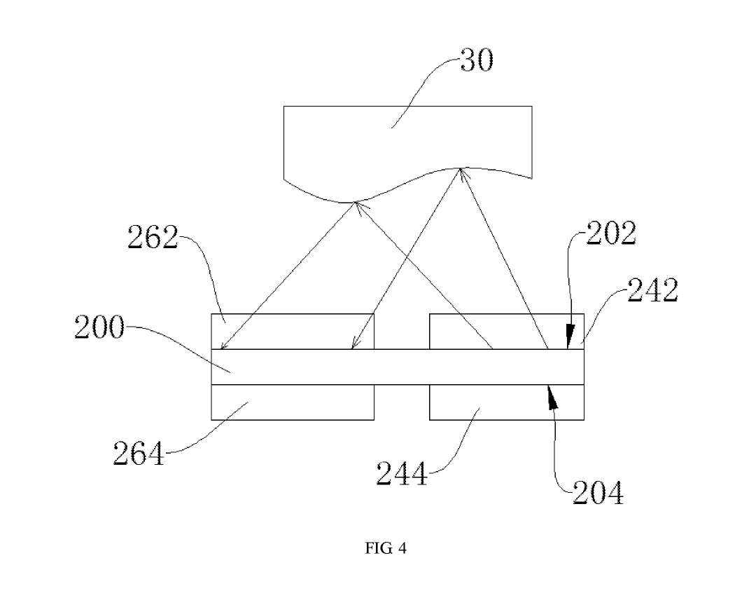

Referring to FIG. 2 and FIG. 3, each pixel area 10 includes a pixel unit 100 and an fingerprint recognition unit 120, which are adjacent to each other. The pixel unit 100 is used to emit colorful image light, the fingerprint recognition unit 120 includes a sensing light emitting module 122 and a sensing light receiving module 124. The sensing light emitting module 122 is used to emit sensing light to a finger, and the sensing light receiving module 124 is used to receive the sensing light reflected by the finger and convert a light signal of the sensing light into an electric signal and send it to a motherboard 40 to process. Since the valley and the ridge of fingerprint have different reflection characteristics of light, the light intensity reflected into the sensing light receiving module 124 corresponding to the valley and ridge of fingerprint is different, therefore the sensing light receiving module 124 generates different current. By means of analyzing the current of the sensing light receiving module 124, what they correspond to the valley or ridge of the fingerprint can be informed and the image of the fingerprint can be acquired finally.

The pixel area 10 displays the image via the pixel unit 100 and recognizes the fingerprint with optical fingerprint recognition technology via the fingerprint recognition unit 120, thus the OLED display technology is integrated with the fingerprint recognition technology. A plurality of pixel areas 10 are arranged to form the OLED display panel 50 to achieve the full-screen fingerprint recognition, the structure of which is simple and the fingerprint recognition is accurate, which satisfies the requirement of full-screen fingerprint recognition of the OLED display panel 50.

In the illustrated embodiment, in the thickness direction of the OLED display panel 50, the pixel area 10 includes an upper electrode, an organic luminescent layer 200, and a lower electrode, which are sequentially laminated. The upper electrode includes a first cathode 222, the lower electrode includes a first anode 224. The pixel unit 100 is formed by laminating the first cathode 222, the organic luminescent layer 200, the first anode 224. In one embodiment, the pixel area 10 is an OLED. The organic luminescent layer 200 includes a first side 202 and a second side 204, which are disposed opposite to each other, the first side 202 and the second side 204 of the organic luminescent layer 200 corresponding to the pixel unit 100 are connected to the first cathode 222 and the first anode 224, respectively. Specifically, the organic luminescent layer 200 includes an electron transmission layer, an electron injection layer, a luminescent material layer, a hole injection layer, and a hole transmission layer, which are sequentially laminated, thus forming a P-N junction. In the pixel unit 100, the organic luminescent layer 200 is provided with a first cathode 222 and a first anode 224 connecting to the P-N junction in the forward direction on both sides, respectively, so as to form the OLED to emit light and display. The organic luminescent layer 200 emits image light of three primary colors of red, green and blue according to the different ratio of the luminescent material layer.

Furthermore, the upper electrode further includes a second cathode 242, the lower electrode includes a second anode 244, the sensing light emitting module 122 is formed by laminating the second cathode 242, the organic luminescent layer 200 and the second anode 244. In one embodiment, the sensing light emitting module 122 is an OLED. The first side 202 and the second side 204 of the organic luminescent layer 200 of the sensing light emitting module 122 are connected to the second cathode 242 and the second anode 244 connecting to the P-N junction in the forward direction, respectively, so as to form the OLED. In addition, a gap is formed between the first cathode 222 and the second cathode 242, and a gap is formed between the first anode 224 and the second anode 244. The second cathode 242 and the first cathode 222 of the pixel unit 100 are insulated from each other and work independently, and the second anode 244 and the first anode 224 of the pixel unit 100 are insulated from each other and work independently. In one embodiment, the ratio of the luminescent material layer of the sensing light emitting module 122 can be different from that of the pixel unit 100, i.e., the sensing light emitting module 122 and the pixel unit 100 are two OLEDS emitting light with different wavelength and working independently.

Furthermore, the upper electrode further includes a third anode 262, the lower electrode further includes a third cathode 264, the sensing light receiving module 124 is formed by laminating the third anode 262, the organic luminescent layer 200 and the third cathode 264. The first side 202 and the second side 204 of the organic luminescent layer 200 of the sensing light receiving module 124 are connected to the third anode 262 and the third cathode 264, respectively, and polarity of the third anode 262 and the second cathode 242 is reverse, polarity of the third cathode 264 and the second anode 244 is reverse, which enables the P-N junction of the sensing light receiving module 124 to be connected in the reverse direction, so as to be the photodiode producing current when it is subjected to illumination. The pixel unit 100 and the sensing light emitting module 122 work independently, the image light emitted from the pixel unit 100 is used to display image, the sensing light emitted from the sensing light emitting module 122 is used to be received by the sensing light receiving module 124 to recognize the fingerprint, and the pixel unit 100 and the sensing light emitting module 122 are independently controlled without affecting each other.

Furthermore, a gap is formed between the third anode 262 and the second cathode 242, and a gap is formed between the third cathode 264 and the second anode 244, therefore the sensing light emitting module 122 and the sensing light receiving module 124 are insulated from each other and work independently.

In one embodiment, the sensing light emitting module 122 is an infrared emitter, the sensing light receiving module 124 is an infrared photodiode used to sense the infrared light emitted from infrared emitter. The infrared light is an invisible light, therefore it has no influence on the color of the image formed by the image light. The displaying of the pixel unit 100 and the fingerprint recognition of the fingerprint recognition unit 120 have no influence on each other, so as to enable the OLED display technology to integrate with the fingerprint recognition technology and the OLED display panel 50 to achieve the full-screen fingerprint recognition.

In an alternative embodiment, the sensing light emitting module 122 is a visible light emitter configured to emit the sensing light of a first wavelength, and the sensing light receiving module 124 is the photodiode configured to sense the light of the first wavelength of the sensing light and the image light. When the component material of the photodiode varies, it can sense different light with particular wavelength. The photodiode can receive the sensing light emitted from the sensing light emitting module 122, as well as the light contained in the image light emitted from the pixel unit 100, which has the same wavelength as the sensing light. The more light photodiode receives, the better fingerprint recognition is, so as to enable the OLED display technology to integrate with the fingerprint recognition technology and the OLED display panel 50 to achieve the full-screen fingerprint recognition.

In the illustrated embodiment, the pixel unit 100 includes a first sub-pixel 102, a second sub-pixel 104, and a third sub-pixel 106, which are sequentially arranged. each of the sub-pixel emits light of different colors, and both of the sensing light emitting module 122 and the sensing light receiving module 124 is located on a side of the third sub-pixel 106 away from the second sub-pixel 104. In one embodiment, the first sub-pixel 102 is a blue sub-pixel used to emit a blue light. The second sub-pixel 104 is a green sub-pixel used to emit a green light. The third sub-pixel 106 is a red sub-pixel used to emit a red light. Three primary colors of blue, green and red are combined with each other to form the colorful image. By merit of the method of lighting of the pixel unit 100, the OLED has advantages of broad field of view, almost infinite high contrast, lower power consumption, fast response time and so on.

Furthermore, both of the sensing light emitting module 122 and the sensing light receiving module 124 are adjacent to the third sub-pixel 106, and are located on the side of the third sub-pixel 106 away from the second sub-pixel 104. Specifically, the first sub-pixel 102, the second sub-pixel 104, the third sub-pixel 106 and the fingerprint recognition unit 120 are in the form of rectangles of the same size. The first sub-pixel 102, the second sub-pixel 104, and the third sub-pixel 106 have the same shape and size as the fingerprint recognition unit 120, which is benefit to the design and arrangement of the pixel area 10.

In the illustrated embodiment, the plurality of pixel units 100 form a matrix for an image to be represented, a matrix formed by the plurality of fingerprint units 120 covers overall display areas of the display panel 50. Recognizing the fingerprint with optical fingerprint recognition technology via the fingerprint recognition unit 120, so as to enable the OLED display technology to integrate with the fingerprint recognition technology. A plurality of pixel areas 10 are arranged to form the OLED display panel 50 to achieve the full-screen fingerprint recognition, the structure of which is simple to attain and the fingerprint recognition is accurate, which satisfies the requirement of full-screen fingerprint recognition of the OLED display panel 50.

Referring to FIG. 5, an OLED display panel according to a second embodiment has a similar structure as that of the first embodiment, the difference lies on that the relative position of the fingerprint recognition unit 120 and the pixel unit 100 is different. Specifically, the pixel unit 100 includes the first sub-pixel 102, the second sub-pixel 104, and the third sub-pixel 106, which are sequentially arranged and configured to emit the image light of different colors, respectively. The first sub-pixel 102, the second sub-pixel 104, and the third sub-pixel 106 have a first short edge 1020, a second short edge 1040 and a third short edge 1060, respectively, and the first short edge 1020, the second short edge 1040 and the third short edge 1060 are collinear, the fingerprint recognition unit 120 connects to the pixel unit 100 via the first short edge 1020, the second short edge 1040 and the third short edge 1060.

The pixel area 10 displays the image via the pixel unit 100 and recognizes the fingerprint with optical fingerprint recognition technology via the fingerprint recognition unit 120, so as to enable the OLED display technology to integrate with the fingerprint recognition technology. A plurality of pixel areas 10 are arranged to form the OLED display panel 50 to achieve the full-screen fingerprint recognition, the structure of which is simple to attain and the fingerprint recognition is accurate, which satisfies the requirement of full-screen fingerprint recognition of the OLED display panel 50.

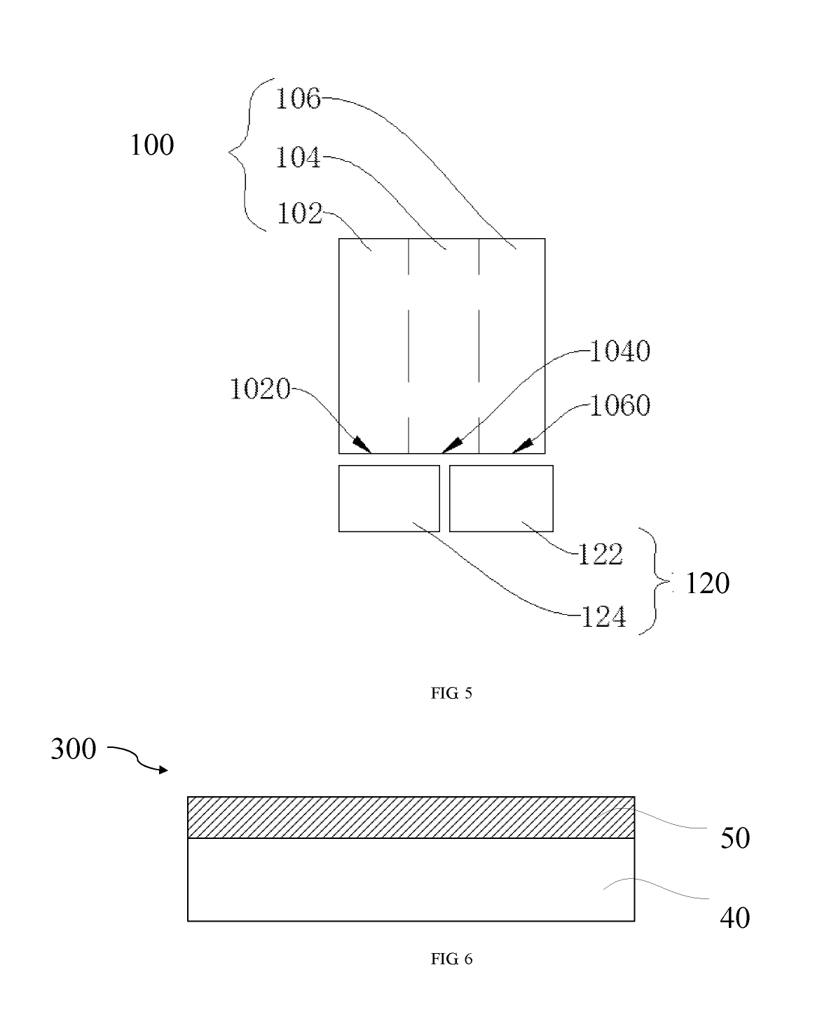

Referring to FIG. 6, the present disclosure is also directed to an electronic device 300, the OLED display device 300 includes a motherboard 40 and an OLED display panel 50 for fingerprint recognition of above. The motherboard 40 is electronically coupled to the OLED display panel 50 and configured to control the pixel unit 100 to display image and process the fingerprint signal emitted from the fingerprint recognition unit 120. When applied in practice, the electronic device 300 may be a terminal with the OLED panel having the fingerprint recognition in the visible area (display area), the terminal may be a mobile phone, a tablet and so on.

The pixel area 10 displays the image via the pixel unit 100 and recognizes the fingerprint with optical fingerprint recognition technology via the fingerprint recognition unit 120, so as to enable the OLED display technology to integrate with the fingerprint recognition technology. A plurality of pixel areas 10 are arranged to form the OLED display panel 50 to achieve the full-screen fingerprint recognition, the structure of which is simple to attain and the fingerprint recognition is accurate, which satisfies the requirement of full-screen fingerprint recognition of the OLED display panel 50.

The foregoing implementations are merely specific embodiments of the present disclosure, but are not intended to limit the protection scope of the present disclosure. It should be noted that persons skilled in the art can understand and embody all or part of flowcharts of the above implementations. Equivalent variation figured out by persons skilled in the art shall all fall within the protection scope of the present disclosure.

What is claimed is:

1. An organic light-emitting diode (OLED) display panel for fingerprint recognition, comprising:
a plurality of pixel areas arranged in arrays, each pixel area comprising:
a pixel unit configured to emit colorful light;
a fingerprint recognition unit adjacent to the pixel unit, the fingerprint recognition unit comprising:
a sensing light emitting module configured to emit sensing light to a finger; and
a sensing light receiving module configured to receive the sensing light reflected by the finger and convert a light signal of the sensing light into an electric signal.

2. The OLED display panel of claim 1, wherein the plurality of pixel units form a matrix for an image to be represented, a matrix formed by the plurality of fingerprint units covers overall display areas of the display panel.

3. The OLED display panel of claim 1, wherein the pixel area comprises an upper electrode, an organic luminescent layer, and a lower electrode, which are sequentially laminated, the upper electrode comprises a first cathode and a second cathode, the lower electrode comprises a first anode and a second anode, the pixel unit is formed by laminating the first cathode, the organic luminescent layer, and the first anode, the sensing light emitting module is formed by laminating the second cathode, the organic luminescent layer and the second anode, and a gap is formed between the first cathode and the second cathode, a gap is formed between the first anode and the second anode, thereby enabling the pixel unit and the sensing light emitting module to work independently.

4. The OLED display panel of claim 3, wherein the upper electrode further comprises a third anode, the lower electrode further comprises a third cathode, the sensing light receiving module is formed by laminating the third anode, the organic luminescent layer, and the third cathode.

5. The OLED display panel of claim 4, wherein a gap is formed between the third anode and the second cathode, and a gap is formed between the third cathode and the second anode.

6. The OLED display panel of claim 3, wherein the organic luminescent layer comprises a first side and a second side, which are disposed opposite to each other, the first side and the second side corresponding to the pixel unit are connected to the first cathode and the first anode, respectively.

7. The OLED display panel of claim 3, wherein the organic luminescent layer comprises an electron transmission layer, an electron injection layer, a luminescent material layer, a hole injection layer, and a hole transmission layer, which are sequentially laminated.

8. The OLED display panel of claim 1, wherein the pixel unit comprises a first sub-pixel, a second sub-pixel, and a third sub-pixel, which are sequentially arranged, each of the sub-pixel emits light of different colors, and the fingerprint recognition unit is located on a side of the third sub-pixel away from the second sub-pixel.

9. The OLED display panel of claim 8, wherein cross-sections of the first sub-pixel, the second sub-pixel, the third sub-pixel and the fingerprint recognition unit are in the form of rectangles of the same size.

10. The OLED display panel of claim 9, wherein the first sub-pixel, the second sub-pixel, and the third sub-pixel have a first short edge, a second short edge and a third short edge, respectively, and the first short edge, the second short edge and the third short edge are collinear, the fingerprint recognition unit is connected to the pixel unit via the first short edge, the second short edge, and the third short edge.

11. The OLED display panel of claim 1, wherein the sensing light emitting module is an infrared emitter, the sensing light receiving module is an infrared photodiode configured to sense infrared light emitted from the infrared emitter.

12. The OLED display panel of claim 1, wherein the sensing light emitting module is a visible light emitter configured to emit the sensing light of a first wavelength, and the sensing light receiving module is the photodiode configured to sense the light of the first wavelength of the sensing light and the image light.

13. An electronic device, comprising:
an OLED display panel comprising:
a plurality of pixel areas arranged in arrays, each pixel area comprising:
a pixel unit configured to emit colorful light;
a fingerprint recognition unit adjacent to the pixel unit, the fingerprint recognition unit comprising:
a sensing light emitting module configured to emit sensing light to a finger; and
a sensing light receiving module configured to receive the sensing light reflected by the finger and convert a light signal of the sensing light into an electric signal; and
a motherboard electrically coupled to the OLED display panel, wherein the motherboard is configured to control the pixel unit to display image and process the electric signal.

14. The electronic device of claim 13, wherein the plurality of pixel units form a matrix for an image to be represented, a matrix formed by the plurality of fingerprint units covers overall display areas of the display panel.

15. The electronic device of claim 13, wherein the pixel area comprises an upper electrode, an organic luminescent layer, and a lower electrode, which are sequentially laminated, the upper electrode comprises a first cathode and a second cathode, the lower electrode comprises a first anode and a second anode, the pixel unit is formed by laminating the first cathode, the organic luminescent layer, and the first anode, the sensing light emitting module is formed by laminating the second cathode, the organic luminescent layer and the second anode, and a gap is formed between the first cathode and the second cathode, a gap is formed between the first anode and the second anode, thereby enabling the pixel unit and the sensing light emitting module to work independently.

16. The electronic device of claim 15, wherein the upper electrode further comprises a third anode, the lower electrode further comprises a third cathode, the sensing light receiving module is formed by laminating the third anode, the organic luminescent layer and the third cathode.

17. The electronic device of claim 16, wherein a gap is formed between the third anode and the second cathode, and a gap is formed between the third cathode and the second anode.

18. The electronic device of claim 15, wherein the organic luminescent layer comprises a first side and a second side, which are disposed opposite to each other, the first side and the second side corresponding to the pixel unit are connected to the first cathode and the first anode, respectively.

19. The electronic device of claim 13, wherein the pixel unit comprises a first sub-pixel, a second sub-pixel, and a third sub-pixel, which are sequentially arranged, each of the sub-pixel emits light of different colors, and the fingerprint recognition unit is located on a side of the third sub-pixel away from the second sub-pixel.

20. The electronic device of claim 19, wherein cross-sections of the first sub-pixel, the second sub-pixel, the third sub-pixel and the fingerprint recognition unit are in the form of rectangles of the same size.
